(19) United States
(12) Patent Application Publication
(10) Pub. No.: US 2026/0123288 A1
(43) Pub. Date: Apr. 30, 2026

(54) ENHANCING POWER OUTPUT OF MAGNETOELECTRIC FILMS IN MINIATURE DEVICE ENCLOSURES

(71) Applicant: Motif Neurotech, Inc., Houston, TX (US)

(72) Inventors: Amanda Singer, Houston, TX (US); Jia Hu, Houston, TX (US); Elizabeth Commissaris, Houston, TX (US); Steven Goetz, Houston, TX (US); Landan Mintch, Houston, TX (US)

(73) Assignee: Motif Neurotech, Inc., Houston, TX (US)

(21) Appl. No.: 19/372,043

(22) Filed: Oct. 28, 2025

Related U.S. Application Data
(60) Provisional application No. 63/713,991, filed on Oct. 30, 2024.

(51) Int. Cl. H10N 35/80; H10N 35/00

(52) U.S. Cl. CPC H10N 35/80; H10N 35/101

(57) ABSTRACT

The present disclosure relates to improving power output of magnetoelectric (ME) films by fine-tuning different parameters of the films. These parameters may include e.g., resonance frequency, magnetic flux collection, interface adhesion, strain enhancement and coupling coefficient that may be fine-tuned through geometric modifications such as by adjusting thickness or layering, surface area or dimensions such as height and width aspect ratio, and patterning. Other configurations of ME film design may also include incorporating additional elements such as a flux-steering element for capturing more flux, additional coils or adding a bias magnet as a strain enhancer. ME films may offer miniaturization for integration into small-scale devices due to their sensitivity to electric and magnetic field, compact size, and low power consumption.

### CROSS-REFERENCE OF RELATED APPLICATIONS

This application claims priority to U.S. Provisional Ser. No. 63/713,991, filed on Oct. 30, 2024, titled “ENHANCING POWER OUTPUT OF MAGNETOELECTRIC FILMS IN MINIATURE DEVICE ENCLOSURES”. The entire disclosure of the aforementioned application is incorporated by reference herein in its entirety for all purposes.

### BACKGROUND

Magnetoelectric materials are characterized by the ability to convert magnetic energy into electrical energy and vice versa, making these suitable for various technological applications including medical devices, wireless power transfer, Internet of Things (IoT), aerospace applications, environmental sensors and energy harvesting solutions. In recent years, there has been a focus on these materials, particularly magnetoelectric (ME) films for compact, efficient and miniature designs (e.g., of the order of 1 cm). ME films may be particularly useful in these miniature designs due to high sensitivity to magnetic and electric fields and ability to operate at micro and nano scales (e.g., sensing magnetic field as low as nanotesla (nT) and electric fields approximately around microvolts (μV)). The miniature design may be used across a spectrum of fields including microsensrs, micro-actuators, components for micromechanical systems (MEMS). The potential of ME films for self-powering capabilities through energy harvesting can make it a promising solution for devices where compactness, efficiency and reliability may be a concern, for example, miniature medical implants that may be implanted inside or on a human body for targeted drug delivery, neural simulations, and biosensing. The ME films may be leveraged for these medical devices enabling minimal maintenance requirements e.g., wearable health monitors or implantable devices may harvest energy from the mechanical movements or external magnetic field thus reducing frequent replacement of battery.

However, the devices leveraging ME films particularly, miniature devices may face several challenges including power consumption when generating and manipulating magnetic fields that can in turn generate excessive heat, which can be problematic in miniature devices due to limited heat dissipation capabilities. Additionally, when mechanical, electrical or magnetic properties of different components within the ME film do not align or complement each other effectively, it can lead to inefficient energy transfer and suboptimal performance. For example, impedance mismatch may cause reflections and energy losses, magnetic mismatch may cause inefficient flux collection or reduced magnetization, or electromechanical mismatch may cause ME films to operate at suboptimal resonance frequency. Moreover, intrinsic losses in ME materials while converting electric to magnetic energy and vice versa can impact overall power requirements of the devices. Power efficiency in magnetoelectric films may be a concern across various applications as efficient energy conversion may enhance device performance and contribute to its sustainability and cost-effectiveness.

### SUMMARY

Certain embodiments of the present disclosure relate to techniques to enhance power output of the ME films by adjusting one or more parameters of the magnetoelectric (ME) films through geometric modifications. The ME films may be comprising at least one layer of magnetostrictive material configured to be magnetized inducing a mechanical strain when an external magnetic field that is generated by a transmitter coil, is applied. On the magnetostrictive layer, there may be at least one layer of piezoelectric material configured to generate an electrical signal in response to the mechanical strain from the at least one layer of magnetostrictive material. To increase magnetic flux collection, a flux-steering element may be coupled to at least one layer of magnetostrictive material along a longitudinal axis of the magnetostrictive layer. The flux-steering element may have a cross-sectional area at one end that is smaller than a cross-sectional area at another end (e.g., an opposite end). The flux-steering element may be coupled such that the one parallel side with the smaller cross-section is positioned towards the at least one magnetostrictive material.

The ME film may further include an electrical arrangement attached to the at least one layer of piezoelectric material configured to collect the electrical signal generated by the at least one layer of piezoelectric material. The flux-steering element may be curved from two non-parallel sides and configured such that the external magnetic field is applied towards the parallel side with larger cross-section to enhance flux collection. In some examples, the flux-steering element comprises a magnetic material, while in some other examples, the flux-steering element comprises magnetostrictive material resulting in a shape having one side that is towards the magnetic field, larger than the other along the longitudinal axis of the magnetostrictive material.

Another apparatus of the ME film design to use interior volume of a device enclosure efficiently may comprise of an enclosure and multiple ME minifilms that may be obtained by segmenting large ME films into small films (or minifilms). The ME minifilm may comprise of at least one layer of magnetostrictive material configured to respond to an external magnetic field that may be generated by a transmitter coil, inducing a mechanical strain, and at least one layer of piezoelectric material on the at least one layer of magnetostrictive material configured to generate an electrical signal in response to the mechanical strain from the adjacent magnetostrictive material. Multiple ME minifilms may be arranged inside the device enclosure such that the total surface area of the ME minifilms exposed to external forces e.g., magnetic field or mechanical forces improves the amount of energy that can be harvested from external interactions. For example, multiple ME minifilms may be configured along an inner perimeter such that a plane of the minifilms is parallel to a plane of the enclosure with a spacing in between each adjacent ME minifilm. This arrangement of minifilms may increase the volume above the device from which flux can be steered into the ME minifilms when the external magnetic field is applied above the enclosure.

Alternately, ME minifilms may be stacked vertically along a normal axis (i.e., on top of each other) or horizontally along a plane of the enclosure (i.e., side-by-side) for a dense arrangement of minifilms inside the enclosure that in turn may increase power output density generated by the ME minifilms. In these arrangements, ME minifilms may be aligned such that the surface of ME minifilms are parallel to an inner wall, or top (or bottom) of the enclosure, depending upon the direction of the applied magnetic field. In some other examples, multiple ME minifilms may be arranged in multiple layers, where each layer may have a different size or arrangement of ME minifilms.

Since the power transfer is related to the strain created in the magnetostrictive element and the resulting strain created in the piezo element, modifications of the geometry of either to enhance or transfer strain creation may improve power output. For example, one or more hollow shapes e.g., grooves, slots may be configured such that these shapes create empty spaces through the at least one layer of magnetostrictive material, at least one layer of piezo material or both, thereby changing a resonance frequency of the magnetoelectric film. In another geometric design, the ME film may be configured such that the thickness is higher at both sides of the magnetostrictive material along a longitudinal axis of the ME film, as compared to a center of the magnetostrictive material. The thickness of the magnetostrictive material may decrease at regular (or irregular) intervals towards the center along the longitudinal axis. Alternatively, the ME film may be configured such that the thickness is lower at both sides of the magnetostrictive material along the longitudinal axis of the ME film, as compared to the center. This thickness of the magnetostrictive material may increase at regular (or irregular) intervals towards the center along the longitudinal axis.

In some aspects, geometric modification of the magnetoelectric film may further include increasing contact surface area between the magnetostrictive and piezoelectric materials. Using additive or subtractive techniques, layers of magnetostrictive or piezoelectric materials may be fabricated to create non-planar geometries. This configuration may result in adjustment of the contact surface area and, consequently, the coupling properties by varying the non-planar interface surface. For example, both surfaces can be designed with opposite ridge patterns to increase the contact surface area compared to flat planar films.

In some configurations, a bias magnet may be attached to one end of the magnetoelectric film along the longitudinal axis of the ME film. The bias magnet may be positioned such that it enhances the mechanical strain induced in at least one layer of magnetostrictive material.

In some other examples, apparatus of ME film may comprise of an enclosure having a lid to cover one end of the enclosure along a longitudinal axis. The lid of the enclosure may have the largest surface area as compared to the rest of the structure. Therefore, the magnetoelectric film may be embedded along a surface of the lid, perpendicular to the longitudinal axis of the enclosure to increase coverage area. Using this technique, a single large film or several minifilms may be used and/or with other geometric modifications to match design aspects of the lid. For example, ME films may be curved to match the contour of a round device. In other examples, ME films may be trapezoidal or otherwise angled to match the interior volume of the device enclosure. If multiple minifilms are configured following this technique, an interconnection may be implemented through a conductive enabling resonance under magnetic fields according to individual dimensions while allowing for a single electrical connection via the bridging element. This apparatus may further include a plurality of (parallel) coils positioned above the enclosure, configured to generate the external magnetic field in a direction perpendicular to an orientation of the ME film.

In some embodiments, a system is provided that includes one or more data processors and a non-transitory computer readable storage medium containing instructions which, when executed on the one or more data processors, cause the one or more data processors to perform part or all of one or more methods disclosed herein.

In some embodiments, a computer-program product tangibly embodied in a non-transitory machine-readable storage medium, including instructions configured to cause one or more data processors to perform part or all of one or more methods or processes disclosed herein.

In some embodiments, a system is provided that includes one or more means to perform part or all of one or more methods or processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention as claimed has been specifically disclosed by embodiments and optional features, modification and variation of the concepts herein disclosed may be resorted to by those skilled in the art, and that such modifications and variations are considered to be within the scope of this invention as defined by the appended claims.

### BRIEF DESCRIPTION OF THE DRAWINGS

The present disclosure is described in conjunction with the appended figures:

FIG. 1 is a block diagram illustrating an example application of a magnetoelectric (ME) film in wireless power transfer (WPT).

FIG. 2 shows an example illustration of an equivalent circuit model of the ME film when subjected to an external alternating magnetic field.

FIG. 3 illustrates various examples of ME films with different geometries to enhance power efficiency.

FIG. 4 shows various exemplary arrangements of a plurality of ME films that may efficiently utilize interior volume of a device.

FIG. 5 illustrates exemplary geometries of ME films with slots to enhance resonance properties.

FIG. 6 shows illustrative examples of the ME films leveraging a layered structure of magnetostrictive material with nonuniform thickness.

FIG. 7 shows an exemplary arrangement of positioning a bias magnet on one end of the ME film.

FIG. 8 illustrates one or more exemplary arrangements to incorporate a larger ME film within a device enclosure.

### DETAILED DESCRIPTION

Some embodiments of the present disclosure relate to improving power output of magnetoelectric (ME) films by fine-tuning different parameters of the films. These parameters may include e.g., resonance frequency, magnetic flux collection, interface adhesion, strain enhancement and coupling coefficient that may be fine-tuned through geometric modifications such as by adjusting thickness or layering, surface area or dimensions (e.g., height and width), aspect ratio, and patterning. ME films may offer miniaturization for integration into small-scale devices due to their sensitivity to electric and magnetic field, compact size, and low power consumption (e.g., in microwatts (μW) or mW). ME films may comprise of a layered structure having one or more layers of piezoelectric material (e.g., lead zirconate titanate (PZT), polyvinylidene fluoride (PVDF), or composites of these material) that may be deposited on one or more layers of magnetostrictive material having high permeability (e.g., iron, nickel, boron or their alloys such as Metglas, Terfenol-D). ME films may also include additional layers or components (e.g., substrate layer or electrodes that may be attached to piezoelectric layer) depending upon the specific design and application. Under the influence of the magnetic field, the magnetostrictive elements may be magnetized exhibiting changes in dimensions that in turn can induce mechanical strain within the magnetostrictive material. This mechanical strain may be transferred to the adjacent piezoelectric layer that may generate an electrical response.

The geometric modifications for enhancing power output can be done in various ways. For example, to increase flux collection adjustments can be made in directional sensitivity by designing ME films such that it aligns well with a predominant direction of the applied magnetic field. This can be achieved by shaping the magnetostrictive material that is responsible for collecting or directing magnetic flux from its nearby magnetic field e.g., by increasing its surface area (or cross-section) to one side that is exposed to magnetic field and/or leveraging nonsymmetric or non-rectangular magnetostrictive element as opposed to typical rectangular designs. Similarly, a flux-steering element may be used with a shape such that a cross-section on one edge is smaller than a cross-section on an opposite edge. For example, the flux-steering element may have a trapezoidal cross-section that is perpendicular to a receiving edge.

Alternatively, or additionally, the cross-section that is perpendicular to the receiving edge may include a curve or slant. The flux-steering element may include a magnetic material having small reluctance. The curved surface may enable adaptation to the device enclosure that can lead to improved flux collection and strain transfer. In another arrangement, as opposed to one large ME film, multiple ME minifilms may be aligned along the inner surface of the enclosure with a spacing in between each adjacent minifilm such that the longitudinal axis of each ME minifilm is parallel to the surface of the enclosure, thus increasing the area above the device. This arrangement may be consequent in efficient utilization of the enclosure interior space and exposure of a larger portion of ME films to the magnetic field, thereby increasing magnetic flux collection.

In one design, by adjusting resonance frequency of the ME films, power transfer can be improved. At resonance, the magnetostrictive element may undergo larger oscillations, producing higher strain that is transferred to the adjacent piezoelectric layer, thus resulting in increased power output. The resonance of the ME films may be dependent on the mechanical properties such as stiffness (spring constant), mass, and damping. These properties may further be influenced by the geometry of the ME films, for example, geometric modifications such as introducing slots or grooves, may alter the spring constant and mass distribution of the magnetostrictive material. In this configuration, the slots or other shapes can be configured in magnetostrictive material, piezoelectric material or both in various ways, including but not limited to horizontal, vertical, or a combination thereof. These slots can be spaced uniformly (with approximately equal spaces in between) or non-uniformly.

Alternatively, by surface treatment (e.g., roughening), adhesion between the magnetostrictive and piezoelectric materials may be improved resulting in effective transfer of strain. In some examples, by employing non-planar geometries, such as ridged surfaces in magnetoelectric films power output may be enhanced. For example, both surfaces (i.e., magnetostrictive and piezoelectric) may be ridged in opposing patterns to increase the contact surface area compared to flat planar films, thereby improving the coupling between the magnetostrictive and piezoelectric materials. This increased contact area may facilitate more efficient energy transfer. Moreover, the magnetostrictive material may be configured to have nonuniform thicknesses such as layered or stacked configuration to match resonance frequency of the ME film to the excitation source and/or focus strain intensity at particular locations within the ME film.

Applying a dc bias magnet may increase sensitivity to the changes in applied magnetic field by aligning the magnetic domain within the magnetostrictive material, thereby increasing the mechanical strain induced. Positioning the bias magnet at particular locations in reference to the ME film may result in increased power transfer, for example, strategically positioning the bias magnet externally e.g., placing the magnet outside of a medical device enclosure i.e., in a procedure accessory such as a burr hole cover, may allow removal of the magnet for compatibility in MRI scans and freeing up internal space within the device, thus enabling larger films to be integrated. Moreover, the magnetic field can be directed towards the ME films e.g., using the bias magnet attached to one end of the ME film as a strain enhancer (since the magnet may itself experience forces under the changing magnetic field). Another arrangement may involve positioning a central magnet to bias a group of ME films. This central magnet can create a uniform magnetic field biasing multiple films simultaneously. In another design, bias magnet may serve as hybrid role providing mechanical stability (e.g., by damping unwanted vibrations or providing magnetic clamping for holding components in place) and electrical connections (e.g., by enhancing magnetic coupling between coil and ME film or by coated with a conductive material to serve as a part of the electrical circuit).

Properties of an ME film such as height may relate directly to its resonant frequency. To match multiple films to a specific magnetic field frequency, films may be tuned during manufacturing by secondary laser processing to trim features into the edges. Alternatively, the positioning and extent of the electrical connections on the sides may be adjusted to create small differences in tuning. It may also be advantageous to use multiple coils, as opposed to a single coil, to create fields in directions tuned to the orientation of the films in the ME devices. For instance, a device may have ME films perpendicular to the longitudinal axis of the device enclosure enabling a longer or a larger film to be fit into the enclosure volume with coils that direct the fields in this generally perpendicular direction.

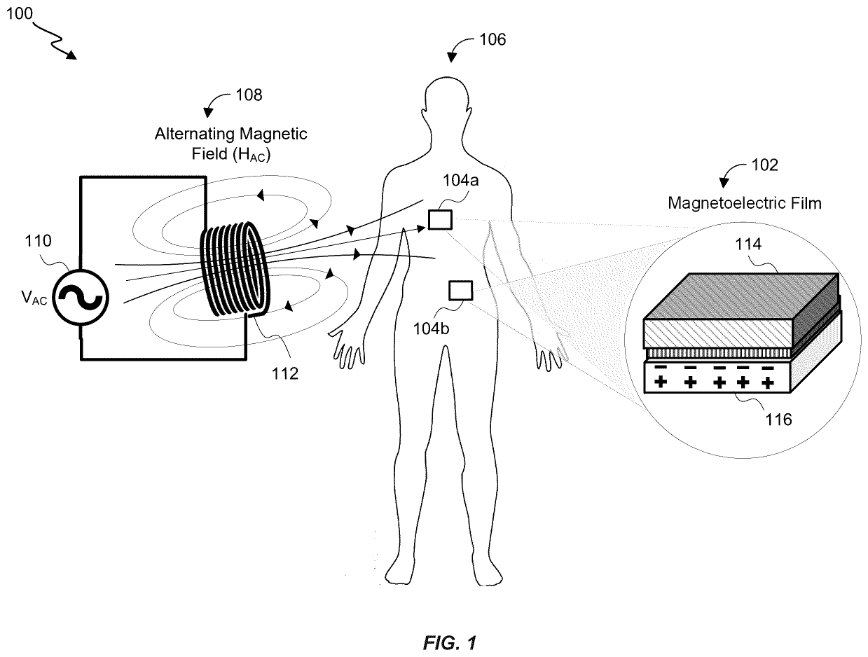

FIG. 1 shows an example illustration 100 of wireless power transfer (WPT) utilizing magnetoelectric (ME) film 102 for one or more medical implants such as 104a and 104b. ME materials may be leveraged in energy harvesting from ambient sources such as vibrations, mechanical movements, and magnetic fields that may be utilized for powering low-power electronic devices in remote or inaccessible locations. ME-enabled WPT may be leveraged for diverse applications eliminating wired connections, for example, ME materials may facilitate wireless charging in consumer electronics (e.g., smartphones, smartwatches, and other portable devices), industrial automation (e.g., robots and electric vehicles), Internet of Things (IoT) and smart cities for deployment of wireless sensors for autonomous environmental monitoring or infrastructure management. Additionally, certain ME materials may be biocompatible and responsive to external stimuli that can be effective to use in biomedical applications such as therapeutic ultrasound, drug delivery systems, tissue engineering i.e., for developing smart biomaterials for tissue regeneration and neural interfaces. ME-based ultrasound devices can generate acoustic waves for non-invasive medical imaging and therapeutic treatments. ME materials can also enhance drug delivery systems by enabling precise control over drug release mechanisms using magnetic and electric fields.

Medical devices, e.g., implants 104a and 104b within or on a human body 106 may require reliable and continuous power sources without the need for invasive procedures to replace batteries. Magnetoelectric films 102, which may combine magnetostrictive and piezoelectric properties may offer a solution by efficiently converting external magnetic fields 108 into electrical energy, thereby providing a sustainable power supply for devices e.g., pacemakers, insulin pumps, and neural stimulators. Wireless power transfer may increase patient comfort by eliminating the need for frequent surgeries, reliability and durability enabling uninterrupted operation of the medical devices. For powering the implants 104a and 104b, an external transmitter coil 112 connected to a voltage source V_{AC} 110 may generate an alternating magnetic field 108. The magnetoelectric film 102 embedded in the implants 104a and 104b, within the vicinity of magnetic field 108, may experience this field as it penetrates through the human body 106. The alternating magnetic field 108 may induce a change in magnetization of the magnetostrictive material 114 (shown by ‘→’ in FIG. 1) that may lead to a mechanical deformation or strain in the material. In response to this deformation, an electric field and a corresponding voltage may be induced in an adjacent piezoelectric layer 116 (shown by ‘+’ and ‘−’). This voltage may be then used (e.g., via electrical connections) to power the implants (104a and 104b) or charge an internal energy storage device, eliminating the need for physical connections or battery replacements. In some examples, the generated electric field from piezoelectric layer 116 may further wirelessly interact with the device in its vicinity.

For medical applications, one or more magnetoelectric films 102 may be arranged within a hermetic or near-hermetic enclosure. This enclosure may be designed for compatibility with implantation or insertion into the human body 106, minimized invasiveness, and miniaturization. ME films 102 may be considered particularly suitable for this application because they can have high output at very small sizes. However, factors such as the geometry of the magnetoelectric film including height (or ratio of height to width), thickness, orientation relative to incident fields, and closeness of spacing may be adjusted to allow efficient power transfer.

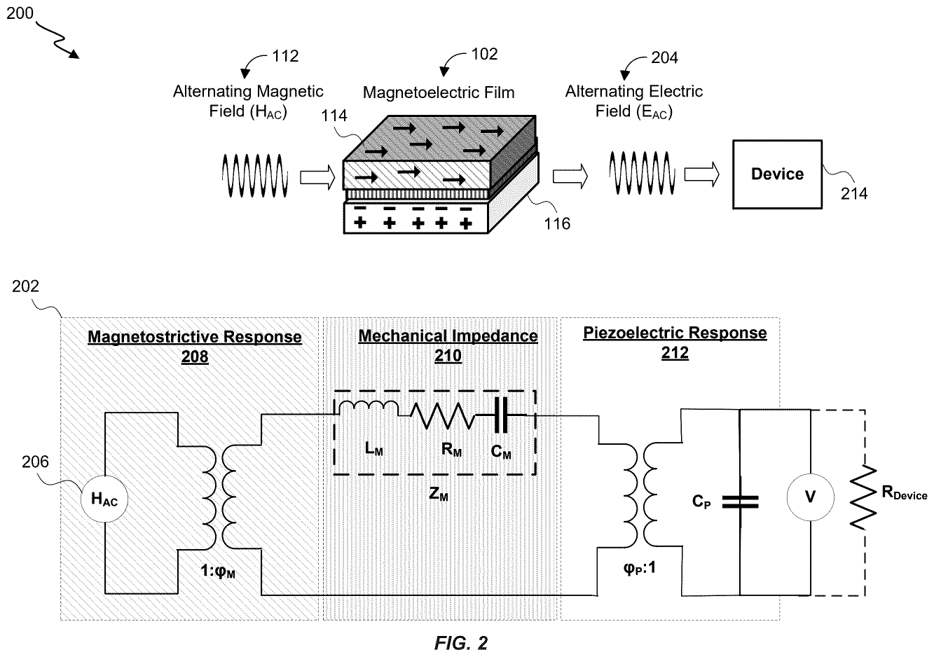

FIG. 2 shows an example illustration 200 of an equivalent circuit model of a magnetoelectric (ME) film 202 when subjected to an external alternating magnetic field 108. The working principle of ME films 102 is the magnetoelectric coupling, where an external magnetic field 108 induces an electrical response and vice versa. The geometry of ME films 102 typically includes a layered structure combining one or more layers of magnetostrictive material 114 and one or more layers of piezoelectric material 116. This composition may generate magnetoelectric effect when an external magnetic field is applied. The magnetostrictive layer 114 is typically made of metallic materials with high permeability such as iron, nickel, boron or their alloys e.g., Metglas, Terfenol-D, which exhibit changes in dimension in response to the applied magnetic field. The magnetostrictive layer 114 may experience changes in strain due to application of alternating magnetic field 108. This strain can induce a mechanical stress within the magnetostrictive material 114 that may be transferred to an adjacent piezoelectric layer 116 comprising of materials such as lead zirconate titanate (PZT), polyvinylidene fluoride (PVDF), or composites of these material. In response, the piezoelectric material 116 may generate an electric field 204 and a corresponding voltage (e.g., across electrodes attached to piezoelectric layer). The amplitude of the voltage can be modulated by shifting the frequency of the applied alternating magnetic field 108.

Apart from magnetostrictive 114 and piezoelectric 116 layers, ME films 102 may include additional layers or components depending upon the specific design and application. These additional layers or components may be incorporated to enhance structural integrity, electrical conductivity or for providing protective coating. For example, a substrate layer that may provide mechanical support, stability, electrical isolation and a foundation upon which the magnetostrictive 114 and piezoelectric 116 layers may be deposited. Moreover, magnetoelectric film 102 may include electrodes that are typically made of conductive materials such as metals (e.g., gold, silver) or conductive polymers. These electrodes may be attached to ME films 102 for applying electric signal to the piezoelectric layer 116 and/or extracting electric signals generated by the piezoelectric effect. Additionally, buffer layers that may comprise of thin conductive layers or insulating layers, may be used to optimize the interference between different materials within the ME film 102 to reduce stress or prevent diffusion between layers. In some applications, ME films 102 may be coated with protective layers or packaged inside an IC (integrated circuit) capsule to enhance durability, resistance to environmental factors (e.g., moisture, corrosion) or biocompatibility for medical applications.

In equivalent circuit model of the ME film 202, H_{AC} 206 may represent the amplitude of the applied alternating magnetic field 108 generated by the transmitter coil 112 that is connected to the voltage source V_{AC} 102. The equivalent magnetic field H_{AC} 206 may induce an elastic excitation or a mechanical stress (used interchangeably herein) in the magnetostrictive layer 114 through a magnetostrictive response 208, which may depend on thickness of the magnetostrictive layer (tₘ). Losses in the elastic excitation may be represented by an equivalent mechanical impedance Z_{M} 210 (alternating current (AC) equivalence of resistance R_{M}, inductance L_{M} and capacitance C_{M}), which may depend on interface adhesion, mechanical quality factor (Q_{M}), total thickness (t) and thickness ratio (η) of the ME film 102. The interface adhesion refers to the bonding strength between two adjacent layers e.g., magnetostrictive 114 and piezoelectric 116 layers. Strong or higher interface adhesion may be consequent in effective transfer of mechanical strain and electrical signals between layers, thereby decreasing energy losses and enhancing power efficiency.

The mechanical quality factor (Q_{M}) in ME films 102 quantifies the efficiency of mechanical energy storage and dissipation. It is a measure of how well a mechanical system or material stores and releases energy during vibrations or oscillations and may be influenced by factors such as material composition, damping mechanisms (including interface adhesion), and the mechanical design of the magnetoelectric film 102. A higher Q_{M} may indicate low energy loss and efficient mechanical response, while a lower Q_{M} may suggest greater energy dissipation and damping. Similarly, the thickness ratio refers to the relative thicknesses of the layers within the ME film 102 structure, such as the magnetostrictive 114 and piezoelectric 116 layers. The thickness ratio may affect mechanical impedance Z_{M} 210 by influencing parameters such as resonant frequencies, mechanical strain distribution, and energy conversion efficiency. Adjusting or fine-tunning the thickness ratio can enhance mechanical resonance and improve the coupling between magnetic and electrical responses, thereby improving energy harvesting or transduction capabilities.

The interface coupling factor (denoted as k), directly related to interface adhesion, refers to the degree of coupling and may be influenced by packaging as well, while the mechanical quality factor (Q_{M}) may be affected by these factors as well as additional considerations such as clamping. The elastic excitation may be converted into an electric field (E_{AC}) 204 through the piezoelectric response 212, where Cp may represent the capacitance of the piezoelectric layer 116. The piezoelectric response 212 may depend on factors such as thickness of piezoelectric layer (tₚ). The resulting electric field 204 can be used to wirelessly power a device 214 e.g., bioimplants. In this equivalent circuit model 202, the voltage difference across the ME film 102 may be represented by V and R_{Device} may account for the device resistance.

Magneto-elastic coupling factor φ_{M}, as illustrated in FIG. 2, quantifies the degree to which the magnetostrictive layer 114 responds to the applied magnetic field 108 by changing its dimension (strain), thus representing the efficiency of the magnetostrictive effect. In other words, the magneto-elastic coupling factor φ_{M} that relates the transfer of the applied magnetic field 108 to an elastic excitation in the magnetostrictive layer 116 depends on the width, magneto-strictive layer thickness, magneto-elastic compliance and piezomagnetic modulus. The induced strain may vary with the frequency and amplitude of alternating magnetic field H_{AC} 108.

Magnetoelectric voltage coefficient, defined as the ratio of the change in receiver open-circuit voltage to the change in the applied magnetic field. This magnetoelectric coefficient may be defined in terms of magneto-elastic and electro-elastic coupling factors (i.e., φₘ and φₚ), equivalent mechanical impedance Z_{M} 210 and the load impedance R_{Device}. Typical design of ME films contemplates one or several generally rectangular films that are positioned vertically in a medical device enclosure (parallel to the incident and generally symmetric magnetic field created by a single coil). One or more techniques are described herein for adjusting different design parameters of the ME films to enhance power output in magnetoelectric films 102.

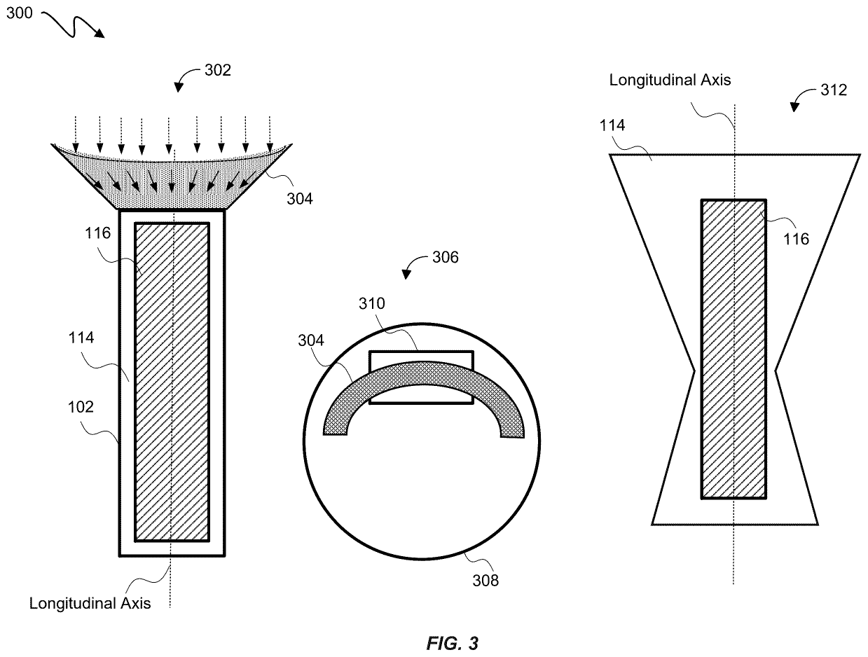

FIG. 3 illustrates various examples of magnetoelectric films (ME) 102 with different geometries to enhance power efficiency. Designing geometry of ME film 102 can enhance its performance, particularly in terms of flux collection. The adjustments in magnetoelectric films 102 can be done in various ways e.g., by adjusting directional sensitivity, adding additional magnetic material (e.g., a flux-steering element), increasing surface area or shaping magnetostrictive material and/or localizing enhancements. Magnetic fields may often be irregular and vary in intensity and direction, hence, by designing ME films such that it aligns effectively with a predominant direction of the magnetic field 108, flux collection may be enhanced. Therefore, flux-steering may be used to selectively change the orientation of fields captured by a magnetoelectric film. For example, flux that is incident perpendicularly to a magnetoelectric film may be steered by a low reluctance element to be more substantially parallel, thereby increasing efficiency of the film.

In some aspects, an ME film arrangement 302, as illustrated in FIG. 3, may include a separate curved shape flux-steering element 304 (e.g., similar to a funnel-like structure that is cut in half) coupled along a longitudinal axis with typical rectangular magnetostrictive 114 and piezoelectric 116 elements. The flux-steering element 304 may comprise of magnetic material having low reluctance and positioned with a device enclosure including ME film 102.

Reluctance is a measure of opposition to magnetic flux that can be reduced by strategically positioning one or more flux-steering elements 304 to capture more flux. When placed in proximity of the ME film 102, these low reluctance elements can direct additional flux towards it, thereby increasing the overall performance of the ME film 102. This approach may be particularly advantageous in medical devices where enhancing efficiency is a concern. Another top view of the ME film arrangement 306, is illustrated in FIG. 3, where a flux-steering element 304 is curved above the ME film 102 that is enclosed within enclosure 308.

Another approach may be the utilization of non-rectangular magnetoelectric (ME) film shapes. Traditionally, ME films may employ symmetric and/or rectangular designs (e.g., 102), which may not be relatively as efficient for flux collection or strain transfer as non-rectangular designs can be. Such shapes can be adjusted for a better flux collection that can lead to an increase in output power of the ME films 102. The magnetostrictive element 114 within the ME film 102 may be responsible for collecting or directing magnetic flux from its surrounding magnetic field 108. The adjustments can be made to the shape of the magnetostrictive element 114 such that it is different in shape than the piezoelectric element 116. Therefore, by shifting from a typical rectangular and/or symmetric shape of the magnetostrictive element 114 to a non-rectangular shape having one side along the longitudinal axis with larger cross-sectional that is exposed to the magnetic field 108, flux collection may be improved. An example of such a non-rectangular ME film 312 that has increased cross-sectional area of the magnetostrictive element 114 at one side along the longitudinal axis is illustrated in FIG. 3. Additionally, the ME films may be curved or molded to match the contour or structure of the device enclosure.

In some other instances, adapting nonplanar or curved magnetostrictive or low reluctance elements to fit curved device enclosures can further increase performance of the ME films 102. Different devices may feature curved surfaces and integrating nonplanar elements that conform to these shapes may be consequent in better coupling with planar piezo element. This adaptation can lead to improved flux collection and strain transfer. The physical properties of magnetostrictive and/or magnetic material (e.g., 304 for steering flux) used in ME films to improve flux collection may be more amenable to shaping or conforming to the device enclosure 308 as compared to piezoelectric material, which may tend to be rigid or brittle. The techniques leveraging these curved or non-planar flux harvesting elements (e.g., magnetostrictive material 114 or magnetic material) may be advantageous particularly for devices e.g., medical devices with irregular shaped or cylindrical enclosures, where the interior surface can be lined with these non-planar elements that are better suited to device geometry.

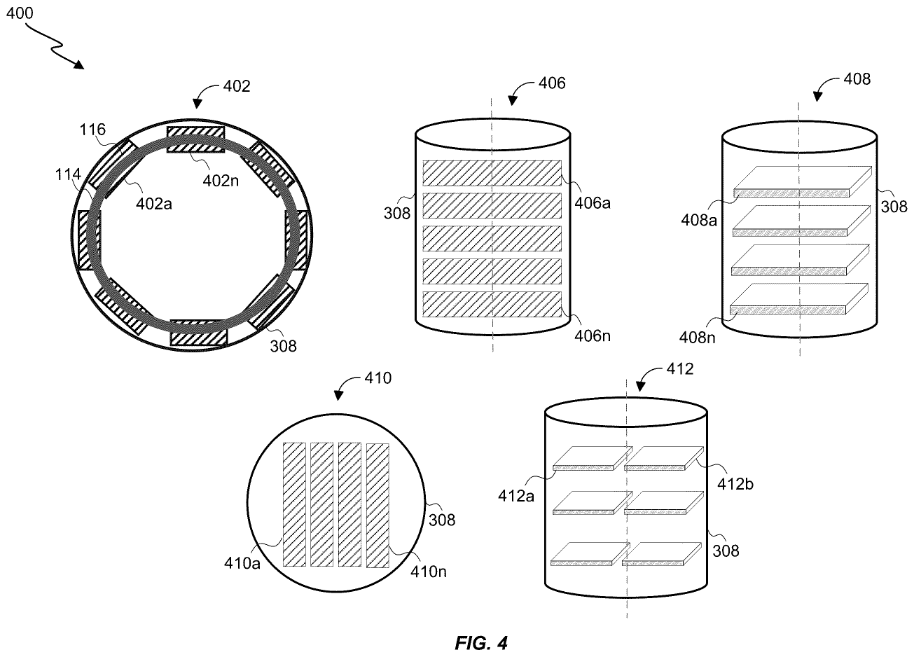

FIG. 4 illustrates exemplary arrangements 400 of a plurality of magnetoelectric films that may efficiently utilize interior volume of a device. In these approaches, large and relatively stiff ME films may be segmented into minifilms comprising magnetostrictive 114 and piezoelectric elements 116. These ME minifilms may be positioned in the interior of the device, increasing coverage to the incident magnetic field 108. Such configurations may enable efficient utilization of the interior space, as compared to a single, large, stiff ME film that may not conform to the irregular or curved shape of the device or enclosure 308. For example, a spatial configuration 402 depicts a top view where a plurality of minifilms 402a, . . . , 402n may be evenly distributed along an inner perimeter of the enclosure 308 such that planes of minifilms are parallel to a top or bottom of the enclosure. The surface of the ME minifilms may be facing either upward or downward, considering the direction of the applied magnetic field. This spatial configuration 402 may lead to a better exposure to the magnetic field 108, thus resulting in enhancement of the volume above the device (or enclosure 308) from which more flux can be steered into the ME minifilms 402a, . . . , 402n.

Treating the stiff piezoelectric element 116 (e.g. with grooves, slots, or other geometrical modifications) can increase its flexibility to bend without fracture. The orientation of the smaller piezoelectric elements 116 along the inner surface of the enclosure 308 can be particularly beneficial for maintaining structural integrity while enabling them to conform more closely to the interior structure of the device or enclosure 308.

In some examples, ME minifilms 406a, . . . , 406n may be stacked vertically inside device enclosure 308 along its axis with uniform or non-uniform spacing between each adjacent ME film. In this stack configuration, the surface of ME films may be aligned towards the interior walls of the enclosure 308, as illustrated in spatial configuration 406 of FIG. 4. Alternately, surface of ME films 408a, . . . , 408n may be aligned along the axis of the enclosure i.e., facing upward or downward as illustrated in spatial configuration 408 of FIG. 4. In some other examples, the plurality of ME minifilms 410a, . . . , 410n may be arranged horizontally, parallel to the top or bottom surfaces of the enclosure 308 as depicted in configuration 410 of the FIG. 4, which shows a top view of the enclosure 308. In both configurations 408 and 410, the ME minifilms may be positioned to enhance vertical forces such as magnetic field or external vibrations acting along the vertical axis of enclosure 308. Additionally, ME minifilms may be arranged stacked horizontally in one layer e.g., 410 or stacked vertically in multiple layers with different sizes and configurations at each layer e.g., as shown in 412 of FIG. 4.

One of the problems while designing the exemplary arrangements 400 of plurality of ME films may be the potential for adjacent minifilms to steal flux from each other. To address this, minifilms may be arranged at spaces (or based on an adjacency metric) such that power is increased for a given flux input while having minimal interference with the neighboring minifilms. These space or adjacency metric may vary with arrangement and film size, for instance, a spacing of approximately 5 mm for minifilms of 6 mm height by 2 mm width might improve flux collection. It should be understood that while the enclosure is illustrated as cylindrical, it can take on various shapes, such as rectangular, spherical, or other irregular forms.

In the context of ME films, effective power transfer may refer to the efficient transfer of mechanical energy from the magnetostrictive element 114 to the piezoelectric element 116, resulting in increased power output. Thus, power transfer in ME films 102 may correlate directly with the strain induced in the magnetostrictive element 114 and subsequent strain transferred to the piezoelectric element 116. Resonance can contribute to efficient power transfer in ME films 102 by amplifying strain within the magnetostrictive material 114, thereby increasing the strain transferred to the piezoelectric element 116. At resonance, the magnetostrictive element 114 may undergo larger oscillations, producing higher strain. The geometry and mechanical properties may contribute to determining the resonance characteristics of ME films 102. For example, in ME films 102, resonance may be dependent on the mechanical properties such as stiffness (spring constant), mass, and damping. These properties may further be influenced by the geometry of the ME films 102, for example, geometric modifications such as introducing slots, grooves, or varying thickness of the magnetostrictive element 114 may alter the spring constant and mass distribution of the magnetostrictive material 114.

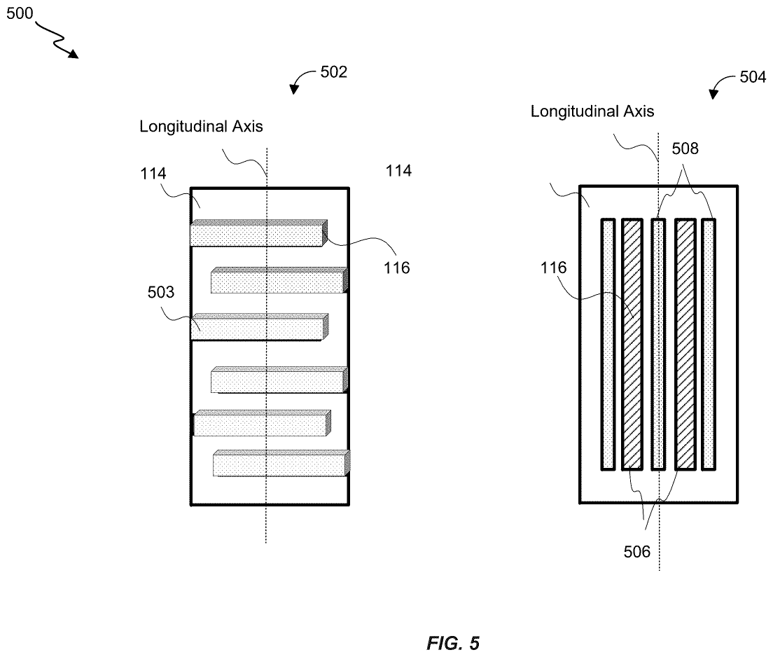

FIG. 5 illustrates one or more exemplary geometries of magnetoelectric (ME) films 500 with slots to enhance resonance properties. These changes can shift the natural frequency of the ME films 102, enabling ME films 102 to resonate in harmony with applied magnetic field 108 at frequencies where enhanced strain transfer between the magnetostrictive material 114 and piezoelectric material 116 may be achieved. In FIG. 5, another exemplary geometric structure of an ME film 502 is illustrated in which the slots are cut through the layered structure of the ME film comprising one or more layers of magnetostrictive material 114 and piezoelectric material 116 (i.e., resulting in hollow slots 503). These hollow slots 503 are arranged horizontally on alternate sides as they move down the length of the ME film along the longitudinal axis.

Similarly, in FIG. 5, another geometric structure of the ME film 504 is illustrated that includes one or more layers of magnetostrictive material 114 deposited over one or more layers of piezoelectric material 116. The structure of the ME film 504 is arranged in such a way that there are vertical hollow slots through the magnetostrictive material 114 (leaving piezoelectric layer intact e.g., at 506), piezoelectric material 116 (not shown) or both (resulting in hollow slots e.g., at 508). The slots may be arranged with uniform or non-uniform spaces, running parallel to each other along the longitudinal axis within the geometric structure of ME film 504.

It should be understood that the geometric structures of the magnetoelectric film 502 and 504 depict two possible arrangements of hollow rectangular shapes i.e., slots within the ME film. However, other shapes can be configured in magnetostrictive material 114, piezoelectric material 116 or both in various ways, including but not limited to horizontal, vertical, or a combination thereof. These hollow shapes can also be regularly or irregularly spaced. The purpose of these hollow shapes or grooves may be to modify the resonance properties of the material. By introducing such geometrical modifications, the spring constant of the material can be altered, as the slots create regions of reduced stiffness, effectively changing the overall mechanical response of the material to external forces.

Another approach to change the resonance properties of the ME film 102 may be to treat the surface for improving adhesion between the magnetostrictive and piezoelectric materials such that the strain is transferred effectively. These surface treatments may involve roughening the surfaces on either a macro or micro scale to improve adhesion that in turn enhances the mechanical coupling. This way, the strain induced in the magnetostrictive material 114 may be transferred more efficiently to the piezoelectric material 116, thus enhancing the performance of the magnetoelectric (ME) devices. In this approach, the magnetostrictive materials 114 may have nonuniform thicknesses such as layered or stacked configurations to focus strain intensity at particular locations within the ME film 102.

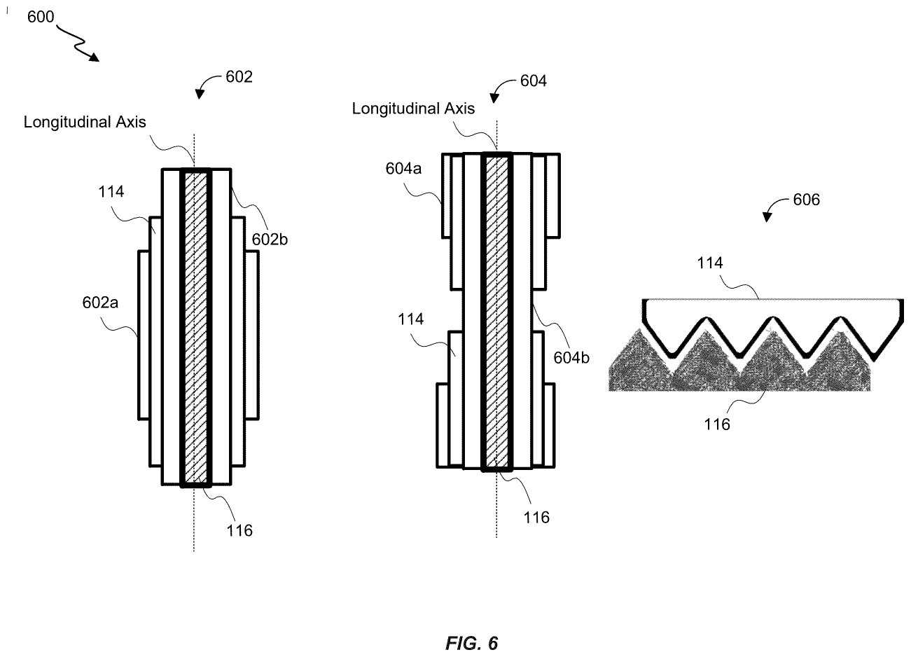

FIG. 6 shows an exemplary illustration 600 of this approach leveraging a layered structure of magnetostrictive material 114 with nonuniform thickness on which a piezoelectric layer 116 is deposited. For example, the thickness of the magnetostrictive material 114 in the middle 602a is higher than the thickness at edge 602b of the exemplary geometric structure 602. This thickness decreases along the longitudinal axis after specified intervals. Similarly, for another exemplary geometric structure 604, the thickness of the magnetostrictive material 114 towards the edges 604a is higher than the thickness at the middle area 604b, where the thickness decreases after specified intervals along the longitudinal axis.

By layering or adjusting thickness of the ME films 102, stiffness, damping and mass distribution can be tailored, which in turn adjusts the resonance frequency of the ME films 102. This nonuniformity may allow better control over the location and intensity of the strain generation thereby enhancing the efficiency of ME films 102.

Additionally, by applying surface treatments such as roughening can improve adhesion between the magnetostrictive and piezoelectric materials. Enhanced adhesion may be consequent effective transfer of strain, preventing energy losses due to slippage or incomplete coupling. Alternatively, or additionally, non-planar geometries, such as ridged surfaces 606, may be employed in magnetoelectric films 102 to enhance power output. For example, both surfaces (i.e., magnetostrictive 114 and piezoelectric 116) may be ridged in opposing patterns to increase the surface area of contact compared to flat planar films, thereby improving the coupling between the magnetostrictive 114 and piezoelectric 116 materials. This increased contact area may facilitate more efficient energy transfer. Additionally, the enhanced strain distribution from these designs may increase sensitivity and responsiveness that may be effective for sensor and actuator applications. The configuration may also change potential resonance effects that further amplify energy conversion processes.

ME films 102 may rely on a direct current (DC) magnet bias to operate effectively, which is typically provided by a small magnet in the vicinity of ME film 102, separately positioned within the enclosure. Approaches to the placement of this bias magnet within the device systems e.g., implants, or sensors can increase magnetic flux collection in the ME films 102. For example, one approach may involve placing the bias magnet outside the device enclosure, such as in a procedure accessory as a burr hole cover. This external placement can free up internal space within the device, enabling more ME films 102 or larger films to be integrated. By strategically positioning the bias magnet externally, the magnetic field can be directed towards the ME films 102. Another approach may involve positioning a central magnet to bias a group of ME films. The central magnet can create a uniform magnetic field biasing multiple film at the same time. This technique can be particularly effective in devices where space is limited, as it reduces the use of multiple individual magnets, thereby simplifying the design and potentially increasing the overall magnetic flux collected by the films.

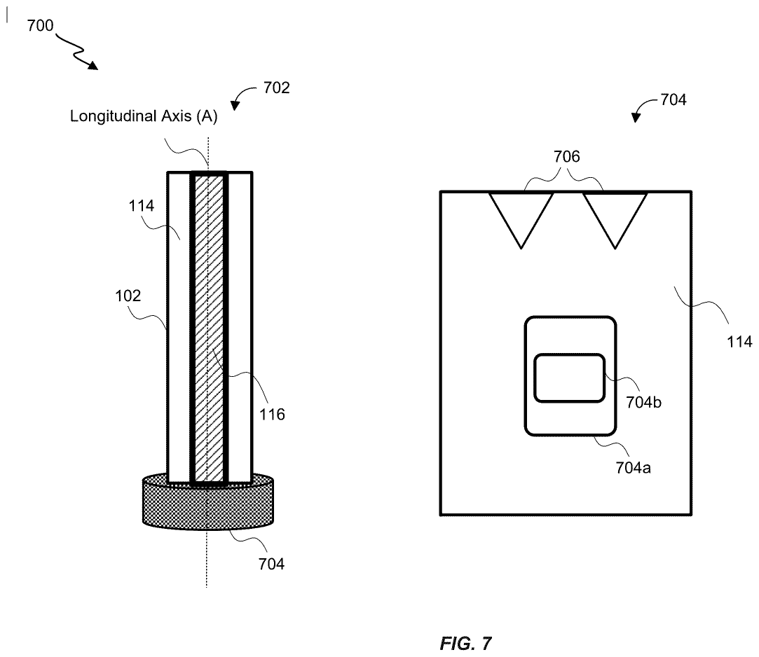

Utilizing the bias magnet in a hybrid role, where it also provides mechanical stability and serves as an electrical connection, can enhance the functionality of the ME devices. By combining these roles, the bias magnet can supply the DC magnetic bias, contribute to the structural integrity of the device and facilitate electrical pathways. This multifunctional use of the bias magnet can lead to more compact and efficient device designs, increasing the power output by making the ME films 102 are both properly biased and structurally supported. Positioning the bias magnet such that it acts as a strain enhancer can further boost power output. FIG. 7 shows an exemplary arrangement 702 of positioning a bias magnet 703 on one end of the ME film 102 along the longitudinal axis. Since the bias magnet 703 itself experiences forces under the changing magnetic field 108, it can contribute to the overall strain experienced by the ME films 102. This additional strain can enhance the magnetostrictive effect, leading to greater mechanical deformation and thus more effective energy conversion in the piezoelectric element 116. By leveraging the forces acting on the bias magnet 703, the overall strain and consequently the power output of the ME films 102 can be enhanced.

As mentioned in the above discussion, the resonant frequency of magnetostrictive material 114 is inherently linked to the physical dimensions, particularly with height. By precisely controlling these dimensions, the films can be fine-tuned to resonate at specific frequencies of the applied magnetic field. During the manufacturing process, secondary laser processing may be employed to trim features into the edges of the films. This method may be leveraged for precise adjustments to the dimensions of the ME film, which in turn, may fine-tune the resonant frequencies. An exemplary illustration of ME film 704 leveraging this method is shown in FIG. 7, where the magnetostrictive material 114 is trimmed along the top edge at 706. The small center pad 704a and large center pads 704b may be leveraged for similar tunning or adjusting the electrical connections on the pad. Alternatively, the ME films 102 may be tuned by adjusting the positioning and extent of the electrical connections on the sides of the films. By creating small differences in the electrical connections, minor variations in the tuning of each film can be achieved, allowing them to resonate in harmony with the target magnetic field frequency. This approach of adjusting electrical connections can be particularly useful when it is impractical to make further physical adjustments to the ME films 102. Thus, by tweaking the electrical aspects, fine-tuning can still be achieved effectively.

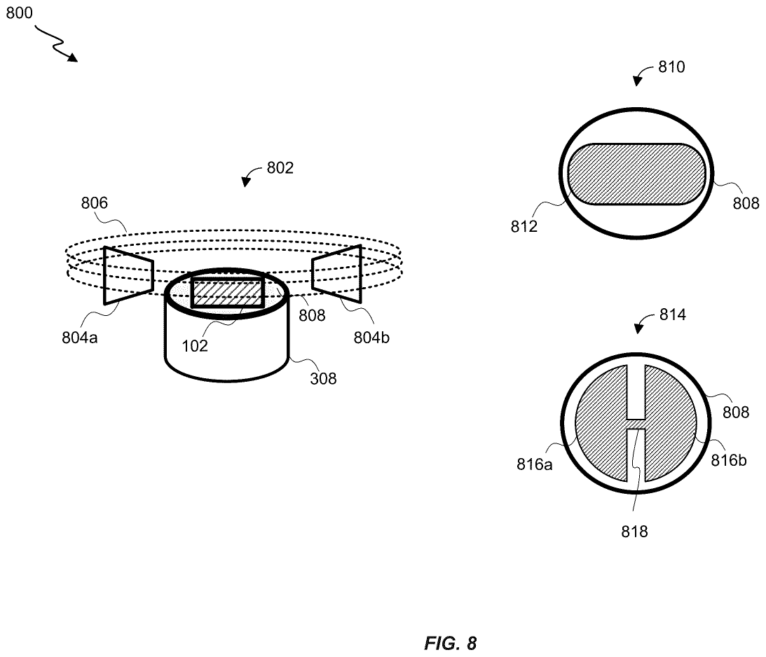

Symmetric magnetic fields are typically created using a single coil; however, it may also be advantageous to use multiple coils to create fields in directions tuned to the orientation of the ME films 102 in the device. For instance, by embedding ME films 102 in a lid covering perpendicular to the axis of device enclosure 308, as illustrated in an exemplary arrangement 802 of FIG. 8, larger ME films can be accommodated within the same volume. In this arrangement 802, ME film 102 can be embedded in the surface of the lid or endcap 808 of enclosure 308, where the lid 808 may feature the largest surface area compared to the rest of the structure. The parallel coils e.g., 804a and 804b then can be arranged accordingly to direct the magnetic fields 806 perpendicularly, thereby enhancing the magnetic flux interaction with the ME films 102. Furthermore, the apparatus may include a plurality of parallel coils positioned above the enclosure, configured to generate an external magnetic field directed perpendicular to the orientation of the ME film.

Following this technique, a single large ME film or multiple minifilms may be leveraged, along with geometric modifications to align with the design of the lid. For example, 810 configuration may leverage a single large ME film 812, that is curved to conform to the contour of a round lid to fit maximum extent of the lid of the device for enhanced power. Additionally, ME films may be trapezoidal or angled to fit the interior volume of the enclosure. If multiple minifilms are arranged using this technique, an interconnection may be implemented through a conductive bridge, enabling the resonance of the ME films under magnetic fields according to individual dimensions while allowing for a single electrical connection via the bridging element. For example, in configuration 814, two ME films 816a and 816b are configured to fit the lid 808 of the device and interconnected by a conductive bridge 818 for an electrical connection for both ME films.

Some embodiments of the present disclosure include a system including one or more data processors. In some embodiments, the system includes a non-transitory computer readable storage medium containing instructions which, when executed on the one or more data processors, cause the one or more data processors to perform part or all of one or more methods and/or part or all of one or more processes disclosed herein. Some embodiments of the present disclosure include a computer-program product tangibly embodied in a non-transitory machine-readable storage medium, including instructions configured to cause one or more data processors to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention as claimed has been specifically disclosed by embodiments and optional features, modification and variation of the concepts herein disclosed may be resorted to by those skilled in the art, and that such modifications and variations are considered to be within the scope of this invention as defined by the appended claims.

The present description provides preferred exemplary embodiments only, and is not intended to limit the scope, applicability or configuration of the disclosure. Rather, the present description of the preferred exemplary embodiments will provide those skilled in the art with an enabling description for implementing various embodiments. It is understood that various changes may be made in the function and arrangement of elements without departing from the spirit and scope as set forth in the appended claims.

Specific details are given in the present description to provide a thorough understanding of the embodiments. However, it will be understood that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

1. A magnetoelectric film comprising:
at least one layer of magnetostrictive material configured to be magnetized inducing a mechanical strain when an external magnetic field that is generated by a transmitter coil, is applied;
at least one layer of piezoelectric material on the at least one layer of magnetostrictive material configured to generate an electrical signal in response to the mechanical strain from the at least one layer of magnetostrictive material; and
a flux-steering element of a trapezoidal shape having a first edge that is of a larger cross-section relative to an opposite second parallel edge, wherein the flux-steering element is coupled to the at least one layer of magnetostrictive material along a longitudinal axis such that the opposite second parallel edge is positioned towards the at least one layer of magnetostrictive material.

2. The magnetoelectric film of claim 1, wherein the flux-steering element is configured such that the external magnetic field is applied towards the first edge of the flux-steering element with larger cross-section to enhance flux collection.

3. The magnetoelectric film of claim 1, wherein the flux-steering element comprises magnetic material.

4. The magnetoelectric film of claim 1, wherein the flux-steering element comprises magnetostrictive material.

5. The magnetoelectric film of claim 1, wherein the flux-steering element is curved from both non-parallel sides.

6. The magnetoelectric film of claim 1, further comprising:
an electrical arrangement attached to the at least one layer of piezoelectric material configured to collect the electrical signal generated by the at least one layer of piezoelectric material.

7. A magnetoelectric film comprising:
at least one layer of magnetostrictive material with a thickness configured to be magnetized inducing a mechanical strain when an external magnetic field that is generated by a transmitter coil, is applied; and
at least one layer of piezoelectric material on the at least one layer of magnetostrictive material configured to generate an electrical signal in response to the mechanical strain from the at least one layer of magnetostrictive material.

8. The magnetoelectric film of claim 7, wherein the at least one layer of the magnetostrictive material further including:
one or more hollow shapes configured to adjust a resonance frequency of the ME film.

9. The magnetoelectric film of claim 7, wherein the at least one layer of the piezoelectric material further including:
one or more hollow shapes configured to alter a resonance frequency of the magnetoelectric film.

10. The magnetoelectric film of claim 7, wherein the thickness of the at least one layer of magnetostrictive material is greater at both sides along a longitudinal axis of the ME film as compared to a center of the at least one layer of magnetostrictive material, wherein the thickness decreases at regular intervals towards the center along the longitudinal axis of the at least one layer of the magnetostrictive material.

11. The magnetoelectric film of claim 7, wherein the thickness of the at least one layer of magnetostrictive material is smaller at both sides along a longitudinal axis of the ME film as compared to a center of the at least one layer of magnetostrictive material, wherein the thickness increases at specified intervals towards the center along the longitudinal axis of the at least one layer of the magnetostrictive material.

12. The magnetoelectric film of claim 7, further comprising:
a bias magnet attached to one end of the magnetoelectric film along a longitudinal axis, wherein the bias magnet is configured to enhance the mechanical strain induced in the at least one layer of magnetostrictive material.

13. The magnetoelectric film of claim 7, further comprising:
an electrical arrangement attached to the at least one layer of piezoelectric material configured to collect the electrical signal generated by the at least one layer of piezoelectric material.

14. An apparatus of a magnetoelectric film comprising:
an enclosure;
a plurality of magnetoelectric (ME) minifilms arranged along an inner perimeter of the enclosure with a spacing in between adjacent ME minifilms of the plurality of ME minifilms, positioned such that a plane of the ME minifilms is parallel to a plane of the enclosure, and wherein the ME minifilms are comprised of:
at least one layer of magnetostrictive material with a thickness configured to be magnetized inducing a mechanical strain when an external magnetic field that is generated by a transmitter coil, is applied; and
at least one layer of piezoelectric material on the at least one layer of magnetostrictive material configured to generate an electrical signal in response to the mechanical strain from the at least one layer of magnetostrictive material.

15. The apparatus of claim 14, wherein the spacing between each adjacent ME minifilms of the plurality of ME minifilms is of an order of a length of the ME minifilm.

16. The apparatus of claim 14, wherein the at least one layer of piezoelectric material and the at least one layer of magnetostrictive material of each ME minifilm of the plurality of ME minifilms are rectangular in shape.

17. The apparatus of claim 14, further comprising:
an electrical arrangement attached to the at least one layer of piezoelectric material of each ME minifilm of the plurality of ME minifilms configured to collect the electrical signal generated by the at least one layer of piezoelectric material.

18. An apparatus comprising:
an enclosure having a lid to cover one end of the enclosure along a longitudinal axis;
a magnetoelectric film that is embedded in the lid along surface of the lid such that the magnetoelectric film is perpendicular to the longitudinal axis of the enclosure, wherein the magnetoelectric film comprises:
at least one layer of magnetostrictive material configured to be magnetized inducing a mechanical strain when an external magnetic field, is applied; and
at least one layer of piezoelectric material on the at least one layer of magnetostrictive element configured to generate an electrical signal in response to the mechanical strain from the at least one layer of magnetostrictive material; and
a plurality of coils positioned above the enclosure, configured to generate the external magnetic field in a direction perpendicular to an orientation of the ME film.
